(19) United States
(12) Patent Application Publication
(10) Pub. No.: US 2007/0077756 A1
(43) Pub. Date: Apr. 5, 2007

(54) Methods of fabricating a fully silicided gate and semiconductor memory device having the same

(76) Inventor: Han Choon Lee, Seoul (KR)

Correspondence Address: MCKENNA LONG & ALDRIDGE LLP;Song K. Jung, 1900 K Street, N.W., Washington, DC, 20006, US

(21) Appl. No.: 11/320,704

(22) Filed: Dec. 30, 2005

(30) Foreign Application Priority Data
Oct. 4, 2005 (KR) 10-2005-0093005

(51) Int. Cl. H01L 21/4763

(52) U.S. Cl. 438/649; 438/651

(57) ABSTRACT

A method of fabricating a semiconductor device having a fully silicided gate, the method includes: forming a gate insulation layer on a substrate; forming a polysilicon layer on the gate insulation film; transforming the polysilicon layer into a silicide layer; patterning the silicide layer to provide a gate electrode; forming a side wall spacer on both side walls of the gate electrode; source and drain regions on both sides of the gate electrode having the side wall spacer; and forming a silicide layer on at least a part of the source/drain regions.

### CROSS-REFERENCE TO RELATED APPLICATION

This application claims the benefit of the Korean Patent Application No. P2005-93005, filed on Oct. 4, 2005, which is hereby incorporated by reference for all purposes as if fully set forth herein.

### BACKGROUND OF THE INVENTION

1. Field of the Invention

The present invention relates to a method of fabricating a semiconductor device, and more particularly, to methods of fabricating having a fully silicide (FUSI) gate in a semiconductor device and a semiconductor device having the same.

2. Description of the Related Art

As semiconductor devices are miniaturized, a polysilicon gate that is usually used in the art has some shortcomings such as high gate resistance, deletion in polysilicon, and boron penetration. Therefore, the polysilicon gate is being substituted with a metal gate. However, since a metal gate composed of pure TiN, TaN, TiSiN, and the like has a nearly constant work function for NMOS or PMOS, the FUSI gate in which silicide fully covers the gate is widely used in the art.

FIGS. 1A through 1J are cross-sectional views illustrating a conventional method of fabricating a fully silicide (FUSI) gate.

As shown in FIG. 1A, a gate oxidation film 11 is formed on a silicon-on-insulator (SOI) substrate 10 having an isolation film (not shown).

As shown in FIG. 1B, a polysilicon gate layer 12 and an oxide hard mask layer 13 are formed on a gate oxidation film 11 through a gate lithography and etching process.

As shown in FIG. 1C, an expanded ion implantation process is performed.

As shown in FIG. 1D, a side wall spacer 14 is formed.

As shown in FIG. 1E, a selective silicon growth is performed to form an expansion area 15 in a source/drain area on the substrate 10.

As shown in FIG. 1F, impurities are implanted into the source/drain region.

As shown in FIG. 1G, a silicide layer 16 having Co is formed on the source/drain region.

As shown in FIG. 1H, a nitride film and an oxidation film 17 are formed.

As shown in FIG. 1I, a chemical-mechanical polishing process is performed to expose the gate.

Finally, as shown in FIG. 1J, the gate 18 is made of Ni and silicide.

The conventional FUSI gate described above with reference to FIGS. 1A through 1J has a work function having nearly the same operative range as that of a typical polysilicon gate due to the dopants such as nitride implanted into the gate, and it overcomes the aforementioned shortcomings of the typical polysilicon gate.

However, since a method of forming a typical FUSI gate should have a chemical-mechanical polishing (CMP) process as shown in FIG. 1I, it is more complicated in comparison with the typical method of forming silicide. Particularly, material properties may be degraded due to scratches or residues generated in the CMP process.

### SUMMARY OF THE INVENTION

Accordingly, the present invention is directed to a method of fabricating a FUSI gate and a semiconductor device having the FUSI gate that substantially obviates one or more of the problems due to limitations and disadvantages of the related art.

Features and advantages of the invention will be set forth in the description which follows, and will be apparent from the description, or may be learned by practice of the invention. The advantages of the invention will be realized and attained by the structure particularly pointed out in the written description and claims hereof as well as the appended drawings.

To achieve the advantages and in accordance with the purpose of the present invention, as embodied and broadly described, there is provided a method of forming a fully silicided gate in a semiconductor device, the method comprising forming a polysilicon layer on a substrate; transforming the polysilicon layer into a silicide layer; and patterning the silicide layer to provide a gate electrode.

According to another aspect of the present invention, there is provided a method of fabricating a semiconductor device having a fully silicided gate, the method comprising forming a gate insulation layer on a substrate; polysilicon layer on the gate insulation film; transforming the polysilicon layer into a silicide layer; patterning the silicide layer to provide a gate electrode; forming a side wall spacer on both side walls of the gate electrode; forming source and drain regions on both sides of the gate electrode having the side wall spacer; and forming a silicide layer on at least a part of the source/drain regions.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention and together with the description serve to explain the principles of the invention. In the drawings:

FIGS. 1A through 1J are cross-sectional views illustrating a conventional method of fabricating a fully silicided gate; and

FIGS. 2A through 2I are cross-sectional views illustrating a method of fabricating a semiconductor device having a fully silicided gate according to an exemplary embodiment of the present invention.

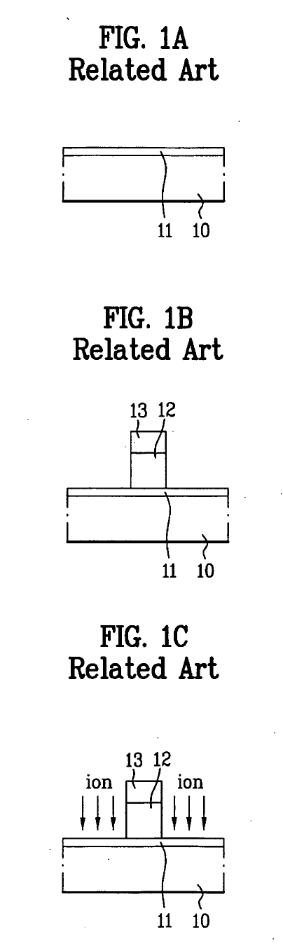

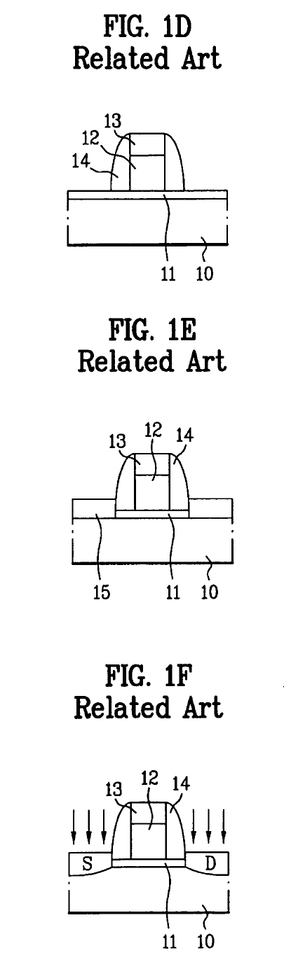

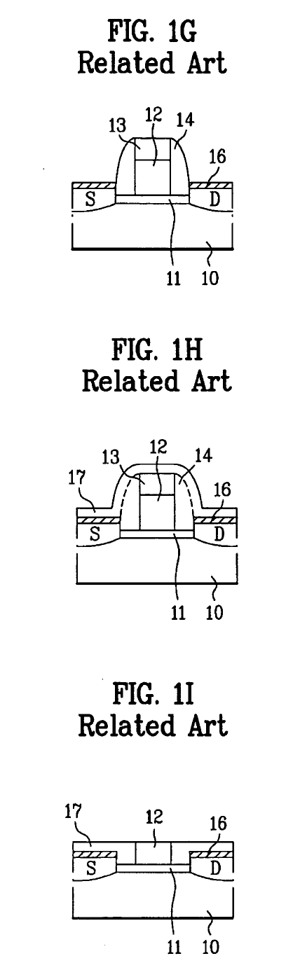

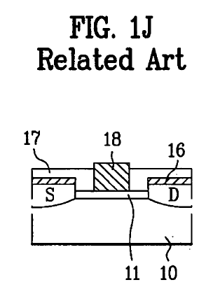

### DETAILED DESCRIPTION OF THE PREFERRED EMBODIMENTS

Reference will now be made in detail to exemplary embodiments of the present invention, examples of which are illustrated in the accompanying drawings.

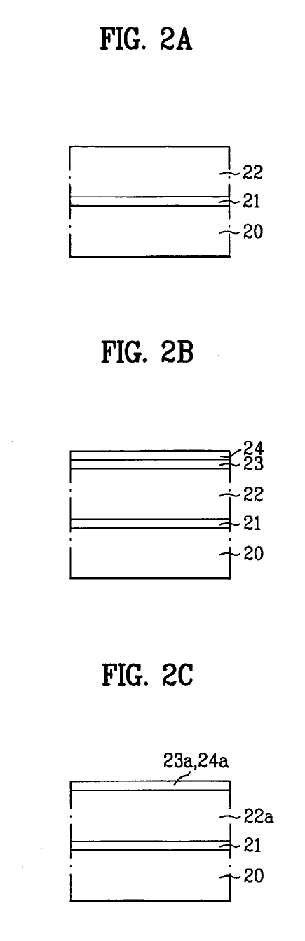

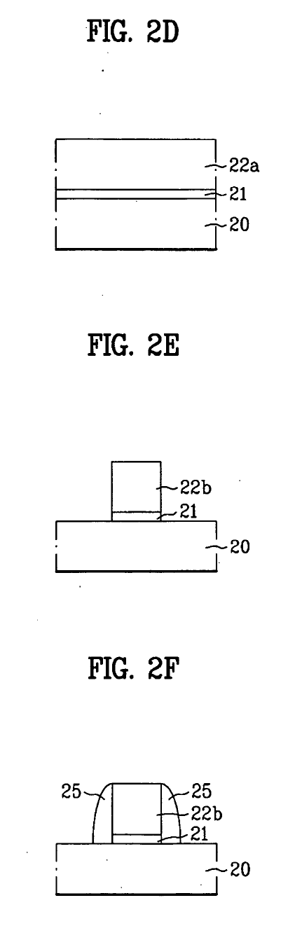

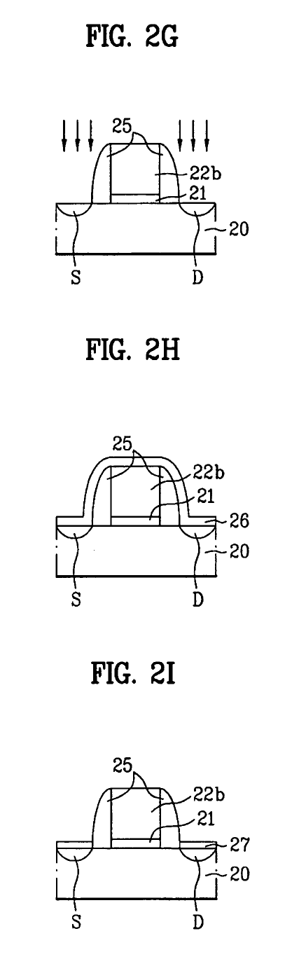

FIGS. 2A through 2I are cross-sectional views illustrating a method of fabricating a semiconductor device having a fully silicided gate according to an exemplary embodiment of the present invention.

As shown in FIG. 2A, an oxide layer 21 as a gate insulation film is provided on a silicon wafer (or a substrate) 20. Then, a polysilicon layer 22 is formed on the gate oxide layer 21. The gate oxide layer 21 and the polysilicon layer 22 may be formed by using a deposition method.

As shown in FIG. 2B, a first metal layer 23 made of Ni and a second metal layer 24 as a capsulation layer made of a material selected from a group consisting of Ti, TiN, and Ti/TiN are sequentially formed on the polysilicon layer 22 to transform the polysilicon layer 22 into an NiSi layer as a silicide layer. The first and second metal layers are formed by using a deposition method.

Alternatively, the first metal layer 23 may be a metal layer having Co. Alternatively, the first metal layer 23 may be a metal layer made of a material selected from a group consisting of Ti, Co, Ni, Mo, and Ta or a combination of them.

Then, the intermediate structure shown in FIG. 2B is thermally treated to transform the polysilicon layer 22 into a metal gate layer 22a as a FUSI layer, as shown in FIG. 2C. The metal layers 23a and 24a disposed on the metal gate layer 22a are residual portions of the first and second metal layers 23 and 24 remained after the thermal treatment.

As shown in FIG. 2D, the residual portions 23a and 24bare removed by a cleaning process using HF.

As shown in FIG. 2E, the metal gate layer 22a and the gate oxide layer 21 are patterned through exposure and etching processes to provide a FUSI gate electrode 22b.

As shown in FIG. 2F, a silicon oxide or a silicon nitride layer is formed on the entire intermediate structure shown in FIG. 2E and then etched to form a side wall spacer 25 on both sides of the FUSI gate electrode 22b.

As shown in FIG. 2G, impurity ions are implanted into the substrate 20 by using the FUSI gate electrode 22b having the side wall spacer 25 as a mask in order to form source and drain regions S and D. The impurity ions are selected from a group consisting of As, B, P, and In.

Subsequently, as shown in FIG. 2H, the metal layer 26 is formed by using a deposition method in order to reactivate the source/drain regions S/D with silicide.

Finally, as shown in FIG. 2I, the metal layer 26 is patterned and thermally treated to form a source/drain silicide layer 27 on top of the source/drain regions S/D. The silicide layer 27 may be formed by using the method of forming the FUSI gate layer 22a as described above.

According to the present invention, it is possible to exclude a polishing process such as CMP in a method of fabricating a FUSI gate in comparison with conventional ones. Therefore, it is possible to simplify a fabricating method. Furthermore, since scratches and residues are seldom generated, it is possible to improve material properties of a semiconductor device.

It will be apparent to those skilled in the art that various modifications and variations can be made in the present invention without departing from the spirit and scope of the invention. Thus, it is intended that the present invention cover the modifications and variations of the invention provided they come within the scope of the appended claims and their equivalents.

What is claimed is:

1. A method of forming a fully silicided gate in a semiconductor device, the method comprising:
forming a polysilicon layer on a substrate;
transforming the polysilicon layer into a silicide layer; and
patterning the silicide layer to provide a gate electrode.

2. The method according to claim 1, further comprising forming a silicon insulation film between the substrate and the polysilicon layer.

3. The method according to claim 1, wherein transforming the polysilicon layer into a silicide layer comprises:
forming a first metal layer on the polysilicon layer;
forming a second metal layer on the first metal layer; and
thermally treating the first and second metal layers.

4. The method according to claim 3, further comprising removing residual metal layers remained on the silicide layer after the thermal treatment.

5. The method according to claim 3, wherein the first metal layer is composed of a material selected from a group consisting of Ti, Co, Ni, Mo and Ta.

6. The method according to claim 3, wherein the second metal layer is composed of a material selected from a group consisting of Ti, TiN, and Ti/TiN.

7. A method of fabricating a semiconductor device having a fully silicided gate, the method comprising:
forming a gate insulation layer on a substrate;
forming a polysilicon layer on the gate insulation film;
transforming the polysilicon layer into a silicide layer;
patterning the silicide layer to provide a gate electrode;
forming a side wall spacer on both side walls of the gate electrode;
forming source and drain regions on both sides of the gate electrode having the side wall spacer; and
forming a silicide layer on at least a part of the source/drain regions.

8. The method according to claim 7, wherein transforming the polysilicon layer into a silicide layer comprises:
forming a first metal layer on the polysilicon layer;
forming a second metal layer on the first metal layer;
thermally treating the first and second metal layers.

9. The method according to claim 8, further comprising: a process of removing residual metal layers remained on the silicide layer after the thermal treatment.

10. The method according to claim 8, wherein the first metal layer is composed of a material selected from a group consisting of Ti, Co, Ni, Mo and Ta.

11. The method according to claim 8, wherein the second metal layer is composed of a material selected from a group consisting of Ti, TiN, and Ti/TiN.
